(19) United States
(12) Patent Application Publication
(10) Pub. No.: US 2025/0015733 A1
(43) Pub. Date: Jan. 9, 2025

(54) Finger Electrostatic Chuck for High Resistance Substrate Chucking

(71) Applicant: Applied Materials, Inc., Santa Clara, CA (US)

(72) Inventors: Mukund SUNDARARAJAN, Bangalore (IN); Sarath BABU, Singapore (SG); Cheng-Hsiung Matthew TSAI, Cupertino, CA (US); Ananthkrishna JUPUDI, Singapore (SG); Ross MARSHALL, Campbell, CA (US)

(21) Appl. No.: 18/218,794

(22) Filed: Jul. 6, 2023

(51) Int. Cl. H02N 13/00; B23Q 3/15; B23Q 11/12

(52) U.S. Cl. CPC H02N 13/00; B23Q 3/15; B23Q 11/128

(57) ABSTRACT

Embodiments of bipolar electrostatic chucks are provided herein. In some embodiments, a bipolar electrostatic chuck, includes: the electrostatic chuck; and a plurality of electrodes disposed in the electrostatic chuck, wherein the plurality of electrodes include a positive electrode arranged in a first pattern comprising a plurality of first arcuate bands coupled together via first connection fingers that extend radially therebetween and a negative electrode arranged in a second pattern comprising a plurality of second arcuate bands coupled together via second connection fingers that extend radially therebetween, wherein the plurality of first arcuate bands are arranged in an alternating pattern with the plurality of second arcuate bands, wherein there is a gap between the first pattern and the second pattern.

### FIELD

Embodiments of the present disclosure generally relate to substrate processing equipment.

### BACKGROUND

Integrated circuits are made possible by processes which produce intricately patterned material layers on substrate surfaces. Producing patterned material on a substrate requires controlled methods for applying and removing material. Typically, these methods include retaining a substrate or workpiece on a substrate support within a processing chamber, for example, using an electrostatic chuck, such as a bipolar electrostatic chuck. However, the inventors have observed that conventional bipolar electrostatic chucks cannot effectively chuck high resistance substrates, such as epoxy, glass, or Si/glass substrates. For bipolar electrostatic chucks, a higher voltage potential is needed to enable chucking of high resistance substrates. However, the higher voltage potential may lead to issues such as high dielectric breakdown risk, reduced uniformity of backside gas pressure, uneven cooling, and difficulty in de-chucking the substrate.

Accordingly, the inventors have provided herein embodiments of improved bipolar electrostatic chucks.

### SUMMARY

Embodiments of bipolar electrostatic chucks are provided herein. In some embodiments, a bipolar electrostatic chuck, includes: an electrostatic chuck; and a plurality of electrodes disposed in the electrostatic chuck, wherein the plurality of electrodes include a positive electrode arranged in a first pattern comprising a plurality of first arcuate bands coupled together via first connection fingers that extend radially therebetween and a negative electrode arranged in a second pattern comprising a plurality of second arcuate bands coupled together via second connection fingers that extend radially therebetween, wherein the plurality of first arcuate bands are arranged in an alternating pattern with the plurality of second arcuate bands, wherein there is a gap between the first pattern and the second pattern.

In some embodiments, a substrate support includes: an electrostatic chuck; a plurality of electrodes disposed in the electrostatic chuck along a common horizontal plane of the electrostatic chuck, wherein the plurality of electrodes include a positive electrode arranged in a first pattern comprising a plurality of first arcuate bands having a plurality of first fingers extending from one or both sides of each of the first arcuate bands and a negative electrode arranged in a second pattern comprising a plurality of second arcuate bands having a plurality of second fingers extending from one or both sides of each of the second arcuate bands, wherein the plurality of first arcuate bands are arranged in an alternating pattern with the plurality of second arcuate bands, wherein the plurality of first arcuate bands are electrically connected to each other via at least one first finger extending between adjacent ones of the first arcuate bands, wherein the plurality of second arcuate bands are electrically connected to each other via at least one second finger extending between adjacent ones of the second arcuate bands, and wherein there is a gap between the first pattern and the second pattern.

In some embodiments, a substrate support includes: an electrostatic chuck; a plurality of electrodes disposed in the electrostatic chuck, wherein the plurality of electrodes include a positive electrode arranged in a first pattern comprising a plurality of first arcuate bands coupled together via first connection fingers that extend radially therebetween and a negative electrode arranged in a second pattern comprising a plurality of second arcuate bands coupled together via second connection fingers that extend radially therebetween, wherein the plurality of first arcuate bands are arranged in an alternating pattern with the plurality of second arcuate bands, wherein there is a gap between the first pattern and the second pattern; a heat transfer plate coupled to a lower surface of the electrostatic chuck; a positive lead extending through, and insulated from, the heat transfer plate and electrically coupled to the positive electrode; and a negative lead extending through, and insulated from, the heat transfer plate and electrically coupled to the negative electrode.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic cross-sectional side view of a process chamber in accordance with at least some embodiments of the present disclosure.

FIG. 2A depicts schematic side views of a substrate support in accordance with at least some embodiments of the present disclosure.

FIG. 2B depicts schematic side views of a substrate support in accordance with at least some embodiments of the present disclosure.

FIG. 3 depicts a schematic cross-sectional top view of an electrostatic chuck in accordance with at least some embodiments of the present disclosure.

FIG. 4 depicts a schematic cross-sectional top view of a central portion denoted as portion 4 in FIG. 3 of an electrostatic chuck in accordance with at least some embodiments of the present disclosure.

FIG. 5 depicts a schematic cross-sectional top view of an edge portion denoted as portion 5 in FIG. 3 of an electrostatic chuck in accordance with at least some embodiments of the present disclosure.

FIG. 6 depicts a schematic cross-sectional top view of a portion of an electrostatic chuck proximate an electrode terminal denoted as portion 6 in FIG. 3 in accordance with at least some embodiments of the present disclosure.

FIG. 7 depicts a schematic cross-sectional top view of a portion of an electrostatic chuck proximate a lift pin opening denoted as portion 7 in FIG. 3 in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of bipolar electrostatic chucks for use in process chambers are provided herein. Conventional monopolar and bipolar electrostatic chucks cannot effectively chuck high resistance substrates, such as epoxy, glass, Si/glass, or oxide coated substrates. As such, the inventors have developed a bipolar electrostatic chuck that includes an electrode design advantageously having positive and negative electrodes disposed in relative close proximately to each other without touching and in an alternating pattern to provide a gradient force to secure a high resistance substrate to the electrostatic chuck. The electrode design provides strong chucking force to the high resistance substrate to adequately retain and flatten the high resistance substrate, which can be warped in semiconductor production.

The bipolar electrostatic chuck generally contains two coplanar electrodes embedded beneath the support surface of the electrostatic chuck. The two electrodes are biased by either a DC or AC power source. An electric field is created between the two electrodes causing charges to migrate along the underside of the substrate. As such, the substrate and the electrodes accumulate oppositely polarized charges, and the substrate is clamped to a support surface of the bipolar electrostatic chuck. A reduced distance between the coplanar electrodes and the support surface also advantageously improves chucking force.

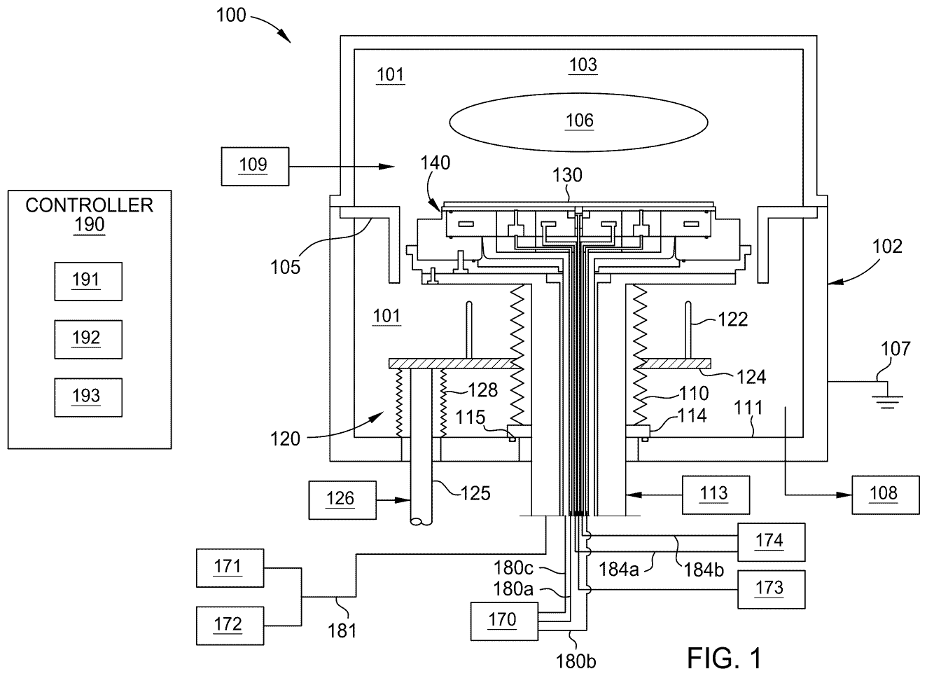

FIG. 1 depicts a schematic cross-sectional side view of a process chamber 100 in accordance with at least some embodiments of the present disclosure. In some embodiments, the process chamber 100 is a pre-clean or deposition chamber. However, process chamber 100 can be configured to complete other processes suitable for semiconductor fabrication and processing. The process chamber 100 is suitably adapted to maintain a processing pressure therein during substrate processing. The process chamber generally includes a chamber body 102 that defines an interior volume 101 therein. A processing volume 103 is located in an upper portion of the interior volume 101. The processing volume 103 may be maintained at sub-atmospheric pressures during processing. The process chamber 100 may also include one or more shields 105 circumscribing various chamber components to prevent unwanted reaction between such components and ionized process material. The chamber body 102 may be made of metal, such as aluminum. The chamber body 102 may also be connected to a ground 107.

The process chamber 100 includes an exhaust 108 to remove gases from the interior volume 101. The processing pressure may be maintained and/or adjusted using the exhaust 108. The exhaust 108 may include one or more pumps. For example, the exhaust may include a throttle valve and vacuum pump. In some embodiments, the exhaust 108 is used to maintain the processing volume 103 at sub-atmospheric conditions. The process chamber 100 is coupled to a gas supply 109 which introduces gases, such as one or more process gases, into the processing volume 103. One or more gases delivered into the processing volume 103 may be ignited into and maintained as a plasma 106 by a substrate support 140.

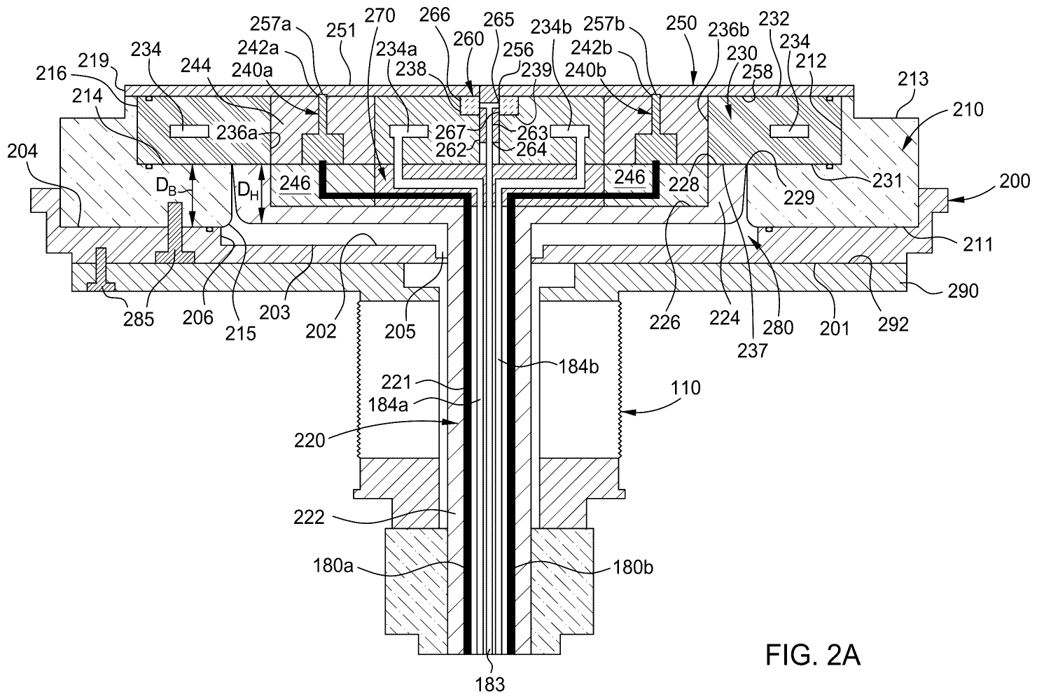

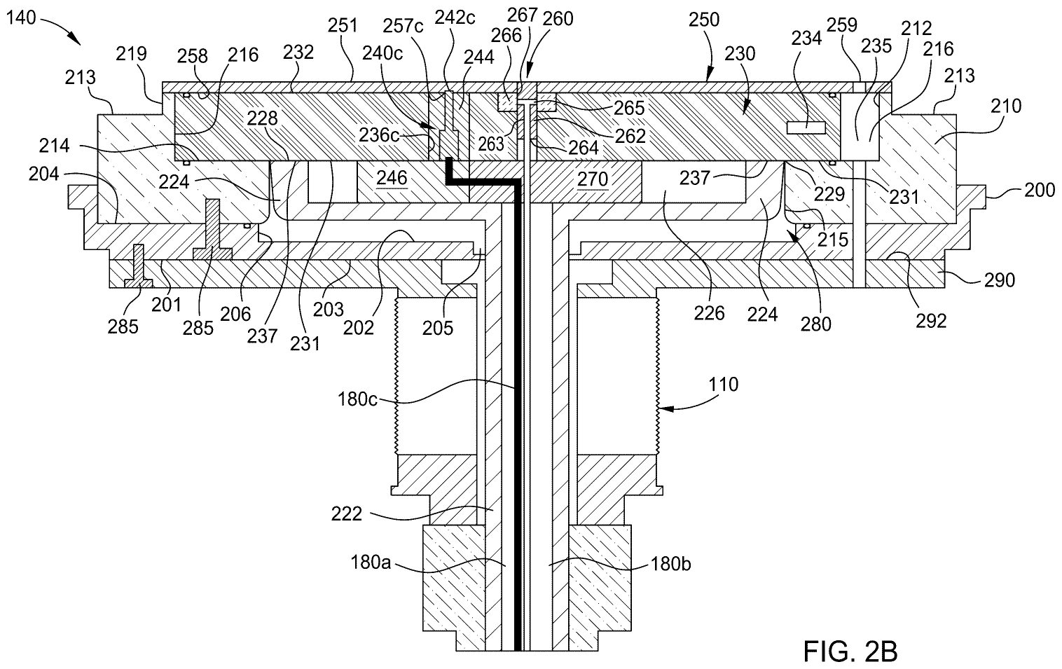

The substrate support 140 is at least partially disposed within the interior volume 101 for supporting and chucking a substrate 130. The substrate 130 is placed on an electrostatic chuck (electrostatic chuck 250 shown in FIG. 2) of the substrate support 140. A chucking power source 170 is coupled to chucking electrodes (e.g., plurality of electrodes 304) in the substrate support 140 by electrical lines 180a and 180b to provide power necessary to chuck the substrate 130 to the substrate support 140. A first RF power supply 171 is connected to the substrate support 140 via a conduit 181 to provide power to ignite the gases within the processing volume 103 to form the plasma 106. A second RF power supply 172 may be connected to the substrate support 140 via the conduit 181 (or separate conduit) to further excite the plasma 106 and to control the plasma 106 during processing of the substrate 130. A heat transfer gas supply 173 may be connected to the substrate support 140 by gas line 183 to provide a heat transfer gas that flows between the underside of substrate 130 and an upper surface of the substrate support 140 to regulate a temperature of the substrate 130. A heat exchanger 174 may be connected to the substrate support 140 to circulate a coolant fluid into the substrate support 140 to regulate the temperature of the substrate 130. The coolant fluid flows into the substrate support 140 through a coolant supply line 184a that returns to the heat exchanger 174 through a coolant return line 184b.

The substrate support 140 may be coupled to a first lift mechanism 113 which provides vertical movement of the substrate support 140 between an upper, processing position (as shown in FIG. 1) and a lower, transfer position (not shown). A bellows assembly 110 is coupled to the substrate support 140 to provide a flexible seal that allows vertical motion of the substrate support 140 while preventing fluid communication between an environment outside the process chamber 100 and the interior volume 101. The bellows assembly 110 may also include a lower bellows flange 114 that is sealed against a bottom surface 111 of the chamber body 102 by one or more seals 115.

The process chamber 100 may also include a lift pin assembly 120 which includes one or more lift pins 122 mounted on a platform 124 connected to a shaft 125. The shaft 125 is coupled to a second lift mechanism 126 for selectively raising and lowering the lift pin assembly 120 relative to the substrate support 140 so that the substrate 130 may be placed on or removed from the electrostatic chuck 250. The substrate support 140 includes openings to receive the lift pins 122 such that the lift pins 122 can engage the underside of the substrate 130. A second bellows assembly 128 may be coupled between the lift pin assembly 120 and the bottom surface 111 to provide a flexible seal which maintains processing pressure during the vertical motion of the lift pin assembly 120.

Operation of the process chamber 100 may be controlled by a controller 190. The controller 190 includes a programmable central processing unit, or CPU 191, which is operable with a memory 192 (e.g., non-volatile memory) and support circuits 193. The CPU 191 is one of any form of general-purpose computer processor used in an industrial setting, such as a programmable logic controller (PLC), for controlling various process chamber components and/or sub/processors. The memory 192, coupled to the CPU 191, facilitates the operation of the process chamber 100. The support circuits 193 are conventionally coupled to the CPU 191 and comprise cache, clock circuits, input/output subsystems, power supplies, and the like, and combinations thereof coupled to the various components of the process chamber 100 to facilitate control of substrate processing operations therewith.

The instructions in memory 192 are in the form of a program product, such as a program that implements the methods of the present disclosure. In some embodiments, the disclosure may be implemented as a program product stored on computer-readable storage media for use with a computer system. Thus, the computer-readable storage media, when carrying computer-readable instructions that direct the functions of the method described herein, are embodiments of the present disclosure.

FIGS. 2A and 2B depict schematic side views of a substrate support in accordance with at least some embodiments of the present disclosure. The substrate support 140 includes a housing 200 coupled to the bellows assembly 110 and a body 210 supported by the housing 200. A lower surface 201 of the housing 200 may be engaged with an upper surface 292 of a flange 290 of the bellows assembly 110 via one or more fasteners 285. An upper surface 202 of the housing may define a housing recess 206. The upper surface 202 may include a shoulder surface 204 radially outward of the housing recess 206 and a bottom surface 203 of the housing recess 206. A port 205 may be formed in the housing 200 and extends from the bottom surface 203 to the lower surface 201. A plurality of lift pin openings corresponding to lift pins 122 may be formed through the housing 200. In some embodiments, the housing 200 is made of a metal, such as aluminum. The housing 200 is generally connected to the ground 107.

In some embodiments, the body 210 includes a body recess 216 defined by an inner upper surface 212 and a shoulder surface 214. An outer upper surface 213 of the body 210 may be disposed radially outward of the body recess 216. A lip 219 may extend vertically upward from the outer upper surface 213. The body 210 may include a central opening 215 that extends from the shoulder surface 214 to a lower surface 211 of the body 210. The housing recess 206, the body recess 216, and the central opening 215 collectively define a cavity 280. The body 210 may at least partially be disposed in the housing recess 206. The outer upper surface 213 may be configured to engage with one or more shield 105 of the process chamber 100. The body 210 may be formed from an insulated material, such as a ceramic, for example, aluminum oxide.

The substrate support 140 may further include an RF transmission tube 220 and a heat transfer plate 230. The RF transmission tube 220 may include a shaft 222 and a head 224 extending radially outward from the shaft 222. The shaft 22 may extend through the port 205 of the housing 200. The head 224 is disposed in the cavity 280. A thickness D_{H} of the head 224 may be the same or substantially the same as a thickness D_{H} of the central opening 215 in the body 210. A bore 221 extends through the shaft 222 and is in communication with a head recess 226 formed in the head 224.

The RF transmission tube 220 is configured to transfer RF power supplies from the first RF power supply 171 and the second RF power supply 172, when present, to the heat transfer plate 230. The electric lines 180a-180c, the coolant supply line 184a, the coolant return line 184b, and the gas line 183 extend through the bore 221 and into the head recess 226. The RF transmission tube 220 may be formed from copper or other material suitable to conduct RF power.

The heat transfer plate 230 includes a lower surface 231 and an upper surface 232. The heat transfer plate 230 may be disposed in the body recess 216 and may generally rest atop the body 210 and the head 224, for example on an upper surface 228 of the head 224. An outside edge 229 of the upper surface 228 is generally in contact with the heat transfer plate 230. In some embodiments, the outside edge 229 is in contact with the body 210 such as contacting an inner sidewall of the body 210 defined by the central opening 215. The heat transfer plate 230 may include coolant channels 234 disposed therein. Coolant fluid circulates through the coolant channels 234 from the heat exchanger 174 to regulate the temperature of the substrate 130 that is disposed on the electrostatic chuck 250. The coolant channel 234 has an inlet 234a connected to the coolant supply line 184a and an outlet 234b connected to the coolant return line 184b.

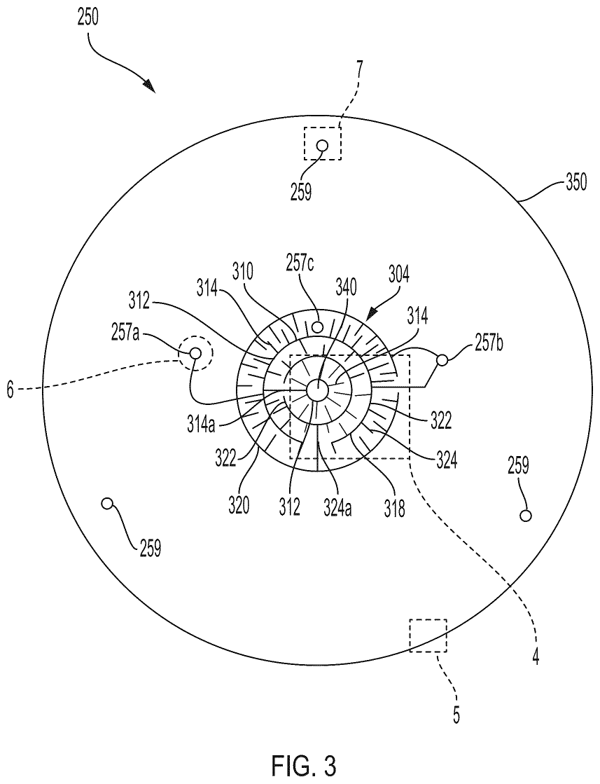

The heat transfer plate 230 also includes a plurality of openings such as a first opening 236a, a second opening 236b, and a third opening 236c to receive a positive lead 240a, a negative lead 240b, and a center tap lead 240c, respectively. The positive lead 240a extends through the heat transfer plate 230 and is electrically coupled to a positive electrode (e.g., positive electrode 308 in FIG. 3) in the electrostatic chuck 250. The negative lead 240b extends through the heat transfer plate 230 and is electrically coupled to a negative electrode (e.g., negative electrode 318 in FIG. 3) in the electrostatic chuck 250. The openings 236a-236c may be spaced to minimize creepage of the chucking voltage supplied to the positive lead 240a and the negative lead 240b through the heat transfer plate 230.

A plug port 238 extends through the heat transfer plate 230 for housing a plug assembly 260. The plug port 238 may extend along a centerline of the heat transfer plate 230 and may include a stop shoulder 239. The upper surface 228 of the head 224 contacts a continuous area 237 of the lower surface 231 of the heat transfer plate 230 that extends around the periphery of openings 236a-236c. In use, RF power is transferred from the RF transmission tube 220 to the heat transfer plate 230 to the electrostatic chuck 250 to generate an electromagnetic field that interacts with gases of the processing volume 103 to ignite a plasma or to maintain or adjust a plasma.

Each lead 240a-240c includes a respective contact 242a, 242b, 242c configured to engage a respective one of a terminal 257a, a terminal 257b, and a terminal 257c disposed in the electrostatic chuck 250. In some embodiments, the terminal 257a is a positive terminal and the terminal 257b is a negative terminal. The terminal 257a and the terminal 257b are coupled to respective electrodes in the electrostatic chuck 250 (described in more detail below with respect to FIG. 3-7).

Each lead 240a-c may be disposed in an insulative plug 244 made of an insulative material to reduce or prevent arcing. As such, the positive lead 240a may extend through and be insulated from the heat transfer plate 230 and be electrically coupled to the position electrode 308. Similarly, the negative lead 240b may extend through and be insulated from the heat transfer plate 230 and be electrically coupled to the negative electrode 318. The leads 240a-240c are positioned in respective openings 236a-c of the heat transfer plate 230. The leads 240a-c may be seated on and supported by a support member 246 disposed in the head recess 226. The leads 240a-c are connected to the chucking power source 170 by a respective electric line 180a-c.

The electrostatic chuck 250 is bipolar because the positive lead 240a and the negative lead 240b are electrically biased relative to each other. In some embodiments, the positive lead 240a and the negative lead 240b each supply a chucking voltage of up to 3000V at opposing polarities to the electrostatic chuck 250 to generate electrostatic force. In some embodiments, the chucking voltage may be about 2500 to about 3500 volts. The voltage at the center tap lead 240c is monitored, for example by controller 190, to determine the voltage drop across the substrate 130. The center tap lead 240c is used to maintain a constant voltage differential on opposite sides of the substrate 130 to keep the substrate chucked to the electrostatic chuck 250.

The electrostatic chuck 250 is generally made of a dielectric material and includes an upper surface 251 and a lower surface 258. The lower surface 258 contacts the leads 240a-c. In some embodiments, the heat transfer plate 230 is coupled to the lower surface 258 of the electrostatic chuck 250. In some embodiments, the heat transfer plate 230 is bonded to the electrostatic chuck 250. Heat transfer gas supplied from the heat transfer gas supply 173 may be delivered to the upper surface 251 via a central gas opening 256 formed in the electrostatic chuck 250. Each lift pin opening 259 formed through the electrostatic chuck 250 is aligned with a corresponding lift pin through-holes 235 of the heat transfer plate 230.

The plug assembly 260 is disposed in the plug port 238 of the heat transfer plate 230 to facilitate flowing heat transfer gas into the channel 254 and the channel 255. The plug assembly 260 generally includes a plug 262 and a sleeve 266. The plug 262 includes a flow path 263. An inlet 264 of the flow path 263 is connected to the heat transfer gas supply 173 via the gas line 183. The plug 262 may also include one or more radial outlets 265 formed on the side of the plug 262. The plug 262 is disposed in a central opening 267 of the sleeve 266. The sleeve 266 may be engaged with the stop shoulder 239 of the heat transfer plate 230. A manifold 270 may be disposed in the head recess 226 beneath the heat transfer plate 230. A portion of at least one of the coolant supply line 184a, the coolant return line 184b, the gas line 183 may be formed in the manifold 270.

FIG. 3 depicts a schematic cross-sectional top view of an electrostatic chuck 250 in accordance with at least some embodiments of the present disclosure. The electrostatic chuck 250 includes a plurality of electrodes 304 comprising a positive electrode 308 and a negative electrode 318 spaced from the positive electrode 308. The plurality of electrodes 304 are coupled to the chucking power source 170 configured to deliver up to about 3500 volts, for example, about 2500 to about 3500 volts. The positive electrode 308 is arranged in a first pattern 310 comprising a plurality of first arcuate bands 312 having a plurality of first fingers 314 extending from one or both sides of each of the first arcuate bands. The plurality of electrodes 304 include a negative electrode 318 arranged in a second pattern 320 comprising a plurality of second arcuate bands 322 having a plurality of second fingers 324 extending from one or both sides of each of the second arcuate bands. While, for simplicity and ease of view, FIG. 3 depicts the plurality of electrodes 304 disposed along a portion of the electrostatic chuck 250, the plurality of electrodes 304 may extend to, or proximate to, an outer edge 350 of the electrostatic chuck 250.

In some embodiments, the positive electrode 308 is coupled to the terminal 257a. In some embodiments, the negative electrode 318 is coupled to the terminal 257b. In the terminal 257c may be spaced from the plurality of electrodes 304 for determining a floating voltage of the electrostatic chuck 250. In some embodiments, the plurality of electrodes 304 are disposed in the electrostatic chuck 250 along a common horizontal plane. In some embodiments, the plurality of first arcuate bands 312 and the plurality of second arcuate bands 322 are arranged in a concentric and alternating manner. In some embodiments, the plurality of first arcuate bands 312 and the plurality of second arcuate bands 322 comprise about 10 to about 20 bands.

The plurality of first arcuate bands 312 are electrically connected to each other via at least one first finger 314a extending between adjacent ones of the first arcuate bands. The plurality of second arcuate bands 322 are electrically connected to each other via at least one second finger 324a extending between adjacent ones of the second arcuate bands. In some embodiments, the plurality of first arcuate bands 312 and the plurality of second arcuate bands 322 extend at least about 350 degrees about a central axis 340 of the electrostatic chuck 250. In some embodiments a distance between the plurality of electrodes 304 and the upper surface 251 of the electrostatic chuck is about 0.25 to about 0.4 mm to provide a suitable electrostatic force on the substrate 130.

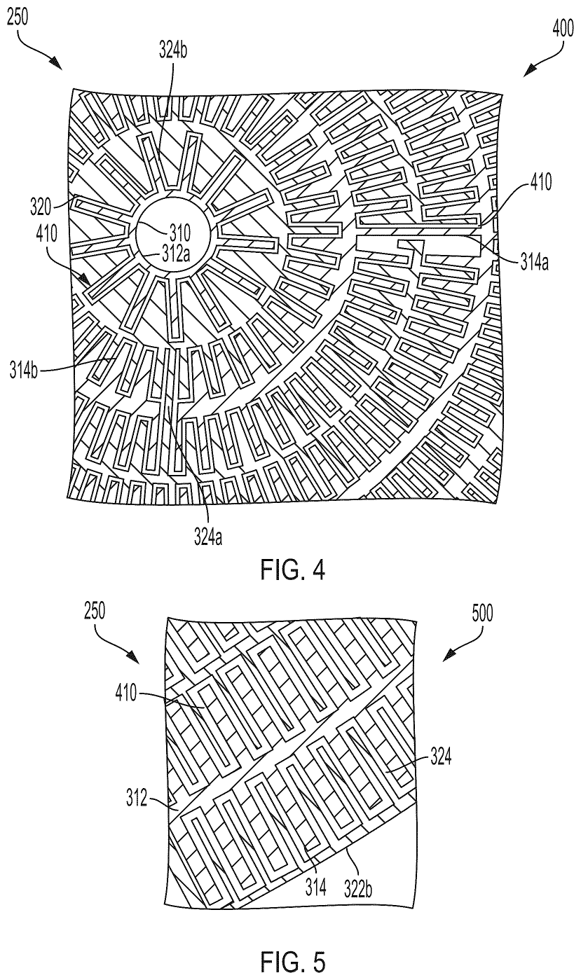

FIG. 4 depicts a schematic cross-sectional top view of a central portion 400 denoted as portion 4 in FIG. 3 of an electrostatic chuck 250 chuck in accordance with at least some embodiments of the present disclosure. The plurality of first arcuate bands 312 are generally arranged in an alternating pattern with the plurality of second arcuate bands 322. In some embodiments, the plurality of first fingers 314 and the plurality of second fingers 324 are generally alternately arranged such that individual first fingers are disposed between adjacent individual second fingers and individual second fingers are disposed between adjacent individual first fingers. A gap 410 is disposed between the first pattern 310 and the second pattern 320. The gap 410 is suitably large enough to prevent arcing between the positive electrode 408 and the negative electrode 418. In some embodiments, the gap 410 is about 0.5 mm to about 1.5 mm.

In some embodiments, the plurality of first fingers 314 have a width of 0.2 mm to 1.0 mm. In some embodiments, at least some of the plurality of first fingers 314 are tapered (e.g. tapered first fingers 314b) so that a width of the first fingers vary along a length of the first fingers. In some embodiments, at least some of the plurality of second fingers 324 are tapered (e.g. tapered second fingers 324b) so that a width of the second fingers vary along a length of the second fingers. In some embodiments, the plurality of first fingers 314 of a radially innermost first arcuate band 312a of the plurality of first arcuate bands 312 extend only radially outward from the radially innermost first arcuate band 312a. In some embodiments, all of the of the plurality of first arcuate bands 312 have a plurality of first fingers 314 extending from both sides of each of the first arcuate bands except for the radially innermost first arcuate band 312a.

FIG. 5 depicts a schematic cross-sectional top view of an edge portion 500 denoted as portion 5 in FIG. 3 of an electrostatic chuck 250 in accordance with at least some embodiments of the present disclosure. In some embodiments, the plurality of second fingers 324 of a radially outermost second arcuate band 322b of the plurality of second arcuate bands 322 extend only radially inward from the radially outermost second arcuate band 322b. In some embodiments, all of the of the plurality of second arcuate bands 322 have a plurality of second fingers 324 extending from both sides of each of the second arcuate bands except for the radially outermost second arcuate band 322b.

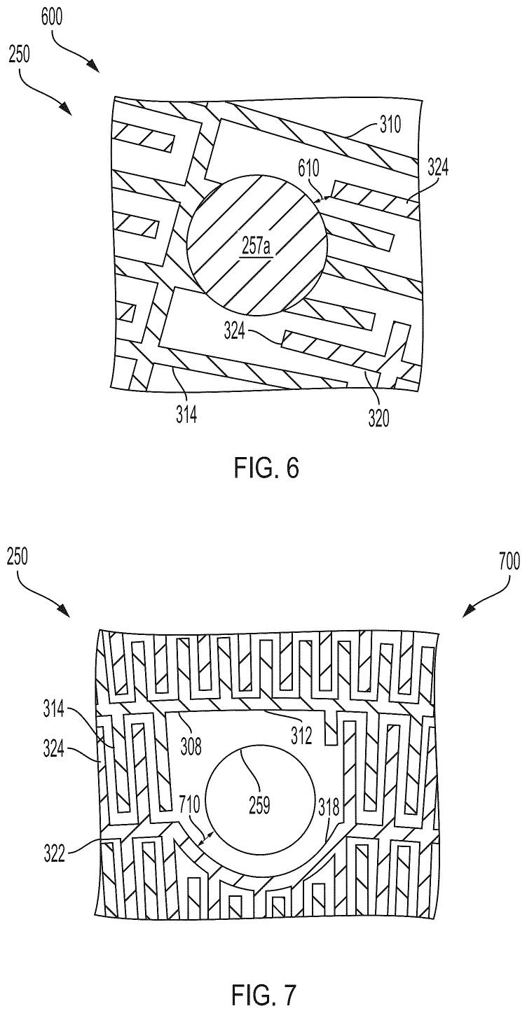

FIG. 6 depicts a schematic cross-sectional top view of a portion 600 of an electrostatic chuck 250 proximate an electrode terminal denoted as portion 6 in FIG. 3 in accordance with at least some embodiments of the present disclosure. For example, FIG. 6 depicts the positive electrode 308 coupled to the terminal 257a. In some embodiments, a second gap 610 is disposed between the terminal 257a and the closest finger of the plurality of second fingers 324 to reduce or prevent arcing. In some embodiments, the second gap 610 is larger than the gap 410. In some embodiments, the second gap 610 is about 0.7 to about 1.5 mm.

FIG. 7 depicts a schematic cross-sectional top view of a portion 700 of an electrostatic chuck 250 proximate a lift pin opening denoted as portion 7 in FIG. 3 in accordance with at least some embodiments of the present disclosure. In some embodiments, there is a third gap 710 between the lift pin opening 259 and the plurality of electrodes 304. In some embodiments, the third gap 710 is about 0.75 to about 3 mm from a closest one of the plurality of electrodes 304.

While the foregoing is directed to embodiments of the present disclosure, other and further embodiments of the disclosure may be devised without departing from the basic scope thereof.

1. A bipolar electrostatic chuck, comprising:
an electrostatic chuck; and
a plurality of electrodes disposed in the electrostatic chuck, wherein the plurality of electrodes include a positive electrode arranged in a first pattern comprising a plurality of first arcuate bands coupled together via first connection fingers that extend radially therebetween and a negative electrode arranged in a second pattern comprising a plurality of second arcuate bands coupled together via second connection fingers that extend radially therebetween, wherein the plurality of first arcuate bands are arranged in an alternating pattern with the plurality of second arcuate bands, wherein there is a gap between the first pattern and the second pattern.

2. The bipolar electrostatic chuck of claim 1, wherein the gap between the first pattern and the second pattern is about 0.5 mm to about 1.5 mm.

3. The bipolar electrostatic chuck of claim 1, wherein the electrostatic chuck includes a central gas opening.

4. The bipolar electrostatic chuck of claim 1, wherein the plurality of first arcuate bands and the plurality of second arcuate bands comprise about 10 to about 20 bands.

5. The bipolar electrostatic chuck of claim 1, wherein the plurality of first arcuate bands include a plurality of first fingers extending from one or both sides of each of the first arcuate bands and the plurality of second arcuate bands include a plurality of second fingers extending from one or both sides of each of the second arcuate bands.

6. The bipolar electrostatic chuck of claim 5, wherein the plurality of first fingers have a width of 0.2 mm to 1.0 mm.

7. The bipolar electrostatic chuck of claim 5, wherein at least some of the plurality of first fingers and at least some of the plurality of second fingers are tapered so that a width of the first fingers and a width of the second fingers vary along a length of the first fingers and a length of the second fingers.

8. The bipolar electrostatic chuck of claim 5, wherein at least one of:
the plurality of first fingers of a radially innermost first arcuate band of the plurality of first arcuate bands extend only radially outward from the radially innermost first arcuate band, or
the plurality of second fingers of a radially outermost second arcuate band of the plurality of second arcuate bands extend only radially outward from the radially outermost second arcuate band.

9. The bipolar electrostatic chuck of claim 5, wherein the plurality of first fingers and the plurality of second fingers are generally alternately arranged such that individual first fingers are disposed between adjacent individual second fingers and individual second fingers are disposed between adjacent individual first fingers.

10. A substrate support, comprising:
an electrostatic chuck; and
a plurality of electrodes disposed in the electrostatic chuck along a common horizontal plane of the electrostatic chuck, wherein the plurality of electrodes include a positive electrode arranged in a first pattern comprising a plurality of first arcuate bands having a plurality of first fingers extending from one or both sides of each of the first arcuate bands and a negative electrode arranged in a second pattern comprising a plurality of second arcuate bands having a plurality of second fingers extending from one or both sides of each of the second arcuate bands, wherein the plurality of first arcuate bands are arranged in an alternating pattern with the plurality of second arcuate bands, wherein the plurality of first arcuate bands are electrically connected to each other via at least one first finger extending between adjacent ones of the first arcuate bands, wherein the plurality of second arcuate bands are electrically connected to each other via at least one second finger extending between adjacent ones of the second arcuate bands, and wherein there is a gap between the first pattern and the second pattern.

11. The substrate support of claim 10, further comprising:
a heat transfer plate coupled to a lower surface of the electrostatic chuck;
a positive lead extending through the heat transfer plate and electrically coupled to the positive electrode; and
a negative lead extending through the heat transfer plate and electrically coupled to the negative electrode.

12. The substrate support of claim 11, further comprising an insulative plug disposed about each of the positive lead and the negative lead.

13. The substrate support of claim 10, wherein the plurality of first arcuate bands and the plurality of second arcuate bands extend at least about 350 degrees about a central axis of the electrostatic chuck.

14. The substrate support of claim 10, wherein a distance between the plurality of electrodes and an upper surface of the electrostatic chuck is about 0.25 to about 0.4 mm.

15. A substrate support, comprising:
an electrostatic chuck;
a plurality of electrodes disposed in the electrostatic chuck, wherein the plurality of electrodes include a positive electrode arranged in a first pattern comprising a plurality of first arcuate bands coupled together via first connection fingers that extend radially therebetween and a negative electrode arranged in a second pattern comprising a plurality of second arcuate bands coupled together via second connection fingers that extend radially therebetween, wherein the plurality of first arcuate bands are arranged in an alternating pattern with the plurality of second arcuate bands, wherein there is a gap between the first pattern and the second pattern;
a heat transfer plate coupled to a lower surface of the electrostatic chuck;
a positive lead extending through, and insulated from, the heat transfer plate and electrically coupled to the positive electrode; and
a negative lead extending through, and insulated from, the heat transfer plate and electrically coupled to the negative electrode.

16. The substrate support of claim 15, wherein the heat transfer plate is bonded to the electrostatic chuck.

17. The substrate support of claim 15, wherein the positive electrode and the negative electrode are coupled to a chucking power source configured to deliver about 2500 to about 3500 volts.

18. The substrate support of claim 15, further comprising heat transfer gas supply connected to the substrate support by gas line to provide a heat transfer gas to an upper surface of the substrate support.

19. The substrate support of claim 15, wherein the heat transfer plate includes coolant channels and further comprising a heat exchanger coupled to the coolant channels via a coolant supply line and a coolant return line.

20. The substrate support of claim 15, wherein the electrostatic chuck includes a plurality of lift pin openings configured to receive a plurality of lift pins configured to selectively raise or lower a substrate over the electrostatic chuck.
